(19) United States
(12) Patent Application Publication
(10) Pub. No.: US 2012/0298171 A1
(43) Pub. Date: Nov. 29, 2012

(54) SOLAR CELL

(75) Inventors: Chiu-Hua Huang, Pingtung County (TW); Cheng-Han Yang, Taichung City (TW); De-Chih Liu, Hsinchu City (TW); Yu-Chun Chen, New Taipei City (TW); Ming-Yuan Huang, New Taipei City (TW); Yi-Chia Chen, Changhua County (TW)

(73) Assignee: AU OPTRONICS CORPORATION, Hsinchu (TW)

(21) Appl. No.: 13/471,444

(22) Filed: May 14, 2012

(30) Foreign Application Priority Data
May 23, 2011 (TW) 100117973
Apr. 24, 2012 (TW) 101114564

(51) Int. Cl. H01L 31/05; H01L 31/0224

(52) U.S. Cl. 136/244; 136/256

(57) ABSTRACT

A solar cell including a photoelectric conversion layer, a back electrode, a plurality of conductive fingers parallel to each other, at least one bus bar and at least one connection ribbon is provided. The photoelectric conversion layer has a front surface and a back surface. The back electrode is disposed on the back surface of the photoelectric conversion layer. The conductive fingers are disposed on the front surface of the photoelectric conversion layer. The at least one bus bar is disposed on the front surface of the photoelectric conversion layer and is electrically connected to the conductive fingers. The connection ribbon covers the bus bar and is electrically connected to the bus bar, wherein the bus bar covered by a single connection ribbon has a discontinuous pattern.

### CROSS-REFERENCE TO RELATED APPLICATION

This application claims the priority benefits of Taiwan application serial no. 100117973, filed on May 23, 2011, and Taiwan application serial no. 101114564, filed on Apr. 24, 2012. The entirety of each of the above-mentioned patent applications is hereby incorporated by reference herein and made a part of specification.

### BACKGROUND OF THE INVENTION

1. Field of the Invention

The invention relates to a solar cell and a solar cell module. Particularly, the invention relates to a cost effective solar cell and a solar cell module.

2. Description of Related Art

Solar energy is a clean, non-polluting, inexhaustible energy source. With the current fossil energy pollution and shortage problems, solar power has been the focus of attention. Since solar cells can directly convert solar energy to electrical energy, solar cells have become a relatively important research topic in current industry. The solar cells have been gradually applied in buildings and electronic products (for example, keyboards, mobile phones and notebook computers, etc). Regardless of the solar cells fixed on the buildings or the solar cells applied in the electronic products, bus bars and conductive fingers used for conducting the electric energy are indispensable components. The commonly used bus bars are generally formed by screen printing, and a material of the bus bar is generally a conductive silver paste.

With a quick development of the solar cell industry, fabrication cost of the solar cell has to be gradually decreased to satisfy a market demand, and reduction of the fabrication cost may increase a market share. Therefore, it is an important issue to reduce the fabrication cost of the solar cell to increase the market share.

### SUMMARY OF THE INVENTION

The invention is directed to a solar cell and a solar cell module, in which a bus bar has a discontinuous pattern.

The invention provides a solar cell including a photoelectric conversion layer, a back electrode, a plurality of conductive fingers parallel to each other, at least one bus bar and at least one connection ribbon. The photoelectric conversion layer has a front surface and a back surface. The back electrode is disposed on the back surface of the photoelectric conversion layer. The conductive fingers are disposed on the front surface of the photoelectric conversion layer. The at least one bus bar is disposed on the front surface of the photoelectric conversion layer and is electrically connected to the conductive fingers. The connection ribbon covers the bus bar and is electrically connected to the bus bar, wherein the bus bar covered by a single connection ribbon has a discontinuous pattern.

The invention provides a solar cell module including a plurality of the aforementioned solar cells, where the solar cells are arranged in an array, and each of the connection ribbons electrically connected to the bus bar extends to the underneath of an adjacent solar cell to electrically connect a back electrode of the adjacent solar cell.

In an embodiment of the invention, an extending direction of the bus bar is different to an extending direction of the conductive fingers.

In an embodiment of the invention, a line width of the bus bar is greater than a line width of the conductive finger.

In an embodiment of the invention, the connection ribbon includes a solder coated copper ribbon.

In an embodiment of the invention, a line width of the connection ribbon is substantially the same to a line width of the bus bar.

In an embodiment of the invention, the number of the at least one bus bar is n, and n is an integer greater than or equal to 2.

In an embodiment of the invention, the discontinuous pattern includes a plurality of bar-shape patterns parallel to each other, and the bar-shape patterns parallel to each other are arranged along a straight line.

In an embodiment of the invention, each of the bar-shape patterns is electrically connected to at least two of the conductive fingers.

In an embodiment of the invention, the bar-shape patterns are electrically connected to each other through at least parts of the conductive fingers.

In an embodiment of the invention, materials of the bus bar and the conductive fingers are substantially the same.

In the solar cell and the solar cell module of the invention, since the bus bar covered by the single connection ribbon has a discontinuous pattern, the material used for fabricating the bus bar can be reduced, so as to reduce the fabrication cost of the solar cell and the solar cell module.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram of a solar cell according to an embodiment of the invention.

FIG. 2 is a schematic diagram of a solar cell module according to an embodiment of the invention.

FIG. 3 is a schematic diagram of a solar cell according to another embodiment of the invention.

FIG. 4 is a schematic diagram of a solar cell according to still another embodiment of the invention.

### DETAILED DESCRIPTION OF DISCLOSED EMBODIMENTS

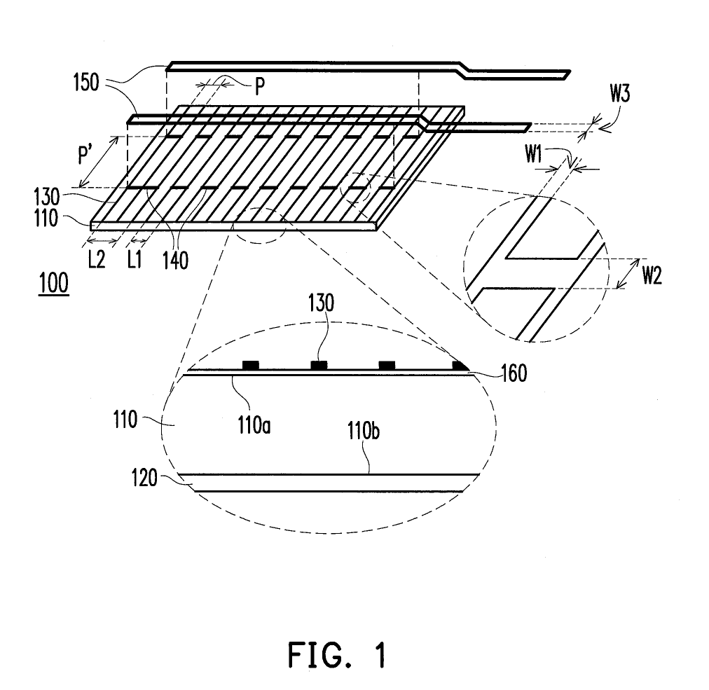

FIG. 1 is a schematic diagram of a solar cell according to an embodiment of the invention. Referring to FIG. 1, the solar cell 100 of the present embodiment includes a photoelectric conversion layer 110, a back electrode 120, a plurality of conductive fingers 130 parallel to each other, at least one bus bar 140 and at least one connection ribbon 150. The photoelectric conversion layer 110 has a front surface 110a and a back surface 110b. The back electrode 120 is disposed on the back surface 110b of the photoelectric conversion layer 110. The conductive fingers 130 are disposed on the front surface 110a of the photoelectric conversion layer 130. The bus bar 140 is disposed on the front surface 110a of the photoelectric conversion layer 110 and is electrically connected to the conductive fingers 130. The connection ribbon 150 covers the bus bar 140 and is electrically connected to the bus bar 140, wherein the bus bar 140 covered by a single connection ribbon 150 has a discontinuous pattern. In the present embodiment, the discontinuous pattern includes a plurality of bar-shape patterns parallel to each other, and the bar-shape patterns parallel to each other are arranged along a straight line.

In the present embodiment, a material of the photoelectric conversion layer 110 is, for example, a-Si or μc-Si, and a thickness thereof is, for example, between 100 μm and 300 μm. In other embodiments, the material of the photoelectric conversion layer 110 is, for example, copper indium gallium selenide (CIGS), copper indium selenide (CIS), copper gallium selenide (CGS), copper gallium telluride (CGT), copper indium aluminium selenide (CIAS), the group II-VI semiconductor or the group III-V semiconductor, and a thickness thereof is, for example, between 100 μm and 300 μm. Moreover, the back electrode 120 is, for example, an aluminium electrode, a silver electrode or an aluminium silver alloy electrode. In addition, an anti-reflection layer 160 can be further disposed on the front surface 110a of the photoelectric conversion layer 110 to increase possibility that the light is incident to the photoelectric conversion layer 110.

The conductive fingers 130 and the bus bars 140 are, for example, formed by screen printing, and a material of the conductive fingers 130 and the bus bars 140 is generally a conductive silver paste or other conductive pastes. Since the conductive fingers 130 and the bus bars 140 are formed in a same fabrication process, the material of the conductive fingers 130 and the bus bars 140 are substantially the same. Moreover, since the bus bars 140 have the discontinuous patterns, the amount of the conductive silver paste used for fabricating the bus bars 140 can be reduced, which facilitates reduction of the fabrication cost.

Generally, the number of the bus bars 140 can be any number, and in the present embodiment, the number of the bus bars 140 is two or three (only two bus bars 140 are illustrated in FIG. 1). For example, an arrangement pitch P of the conductive fingers 130 is smaller than an arrangement pitch P′ of the bus bars 140, and the number of the conductive fingers 130 is greater than the number of the bus bars 140. Moreover, the arrangement pitch P of the conductive fingers 130 is, for example, between 1 mm and 3 mm, and the arrangement pitch P′ of the bus bars 140 is, for example, between 40 mm and 90 mm. In the present embodiment, an extending direction of the bus bars 140 is, for example, different to an extending direction of the conductive fingers 130.

As shown in FIG. 1, each of parts of the bar-shape patterns has a length of L1, and each of the other parts of the bar-shape patterns has a length of L2, wherein the length L1 is substantially equal to the arrangement pitch P of the conductive fingers 130 and the length L2 is substantially equal to twice of the arrangement pitch P. Therefore, in the embodiment, each of the bar-shape patterns is electrically connected to at least two of the conductive fingers 130.

For example, the extending direction of the bus bars 140 is substantially perpendicular to the extending direction of the conductive fingers 130. In detail, the solar cell 100 is, for example, a rectangular solar cell, and the extending direction of the bus bars 140 is, for example, parallel to a long side of the solar cell 100, and the extending direction of the conductive fingers 130 is, for example, parallel to a short side of the rectangular solar cell 100. In other embodiments of the invention, the extending direction of the bus bars 140 is, for example, parallel to the short side of the rectangular solar cell 100, and the extending direction of the conductive fingers 130 is, for example, parallel to the long side of the rectangular solar cell 100. However, it should be noted that the extending directions of the conductive fingers 130 and the bus bars 140 are not limited by the invention, and those skilled in the art can modify the extending directions of the conductive fingers 130 and the bus bars 140 according to a design requirement.

According to FIG. 1, it is known that a line width W2 of the bus bar 140 is, for example, greater than a line width W1 of the conductive finger 130, so that the relatively large line width W2 is used to reduce impedance. The line width W2 of the bus bar 140 is substantially the same to a line width W3 of the connection ribbon 150, so that an effective connection therebetween is achieved and reduction of solar light absorption due to excessive line width W3 is avoided. In other embodiment of the invention, the line width W3 of the connection ribbon 150 can be slightly greater than the line width W2 of the bus bar 140.

In the present embodiment, a good electrical contact between the connection ribbon 150 and the bus bar 140 is generally required, so that the electric energy generated by the solar cell 100 can be effectively collected and conducted. For example, the connection ribbon 150 of the present embodiment is, for example, a solder coated copper ribbon, which has a good electrical contact characteristic with the conductive silver paste.

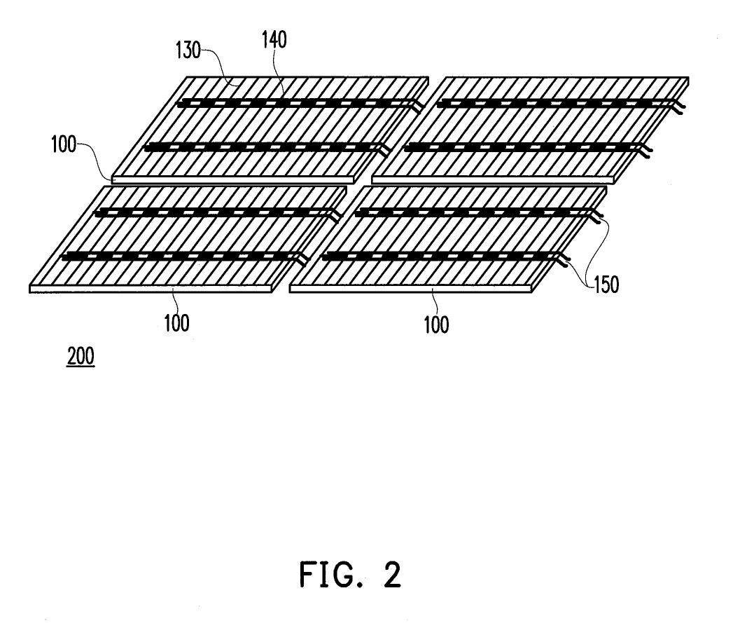

FIG. 2 is a schematic diagram of a solar cell module according to an embodiment of the invention. Referring to FIG. 2, the solar cell module 200 of the present embodiment includes a plurality of the aforementioned solar cells 100. The solar cells 100 are arranged in an array, and each of the connection ribbons 150 electrically connected to the bus bar 140 extends to the underneath of an adjacent solar cell 100 to electrically connect the back electrode 120 of the adjacent solar cell 100. In the present embodiment, the solar cells 100 are arranged in an (m*n) array, where M and n are positive integers. The solar cell module 200 shown in FIG. 2 is formed by the solar cells 100 arranged in a (2*2) array. However, the arrangement and the number of the solar cells 100 in the solar cell module 200 are not limited by the invention.

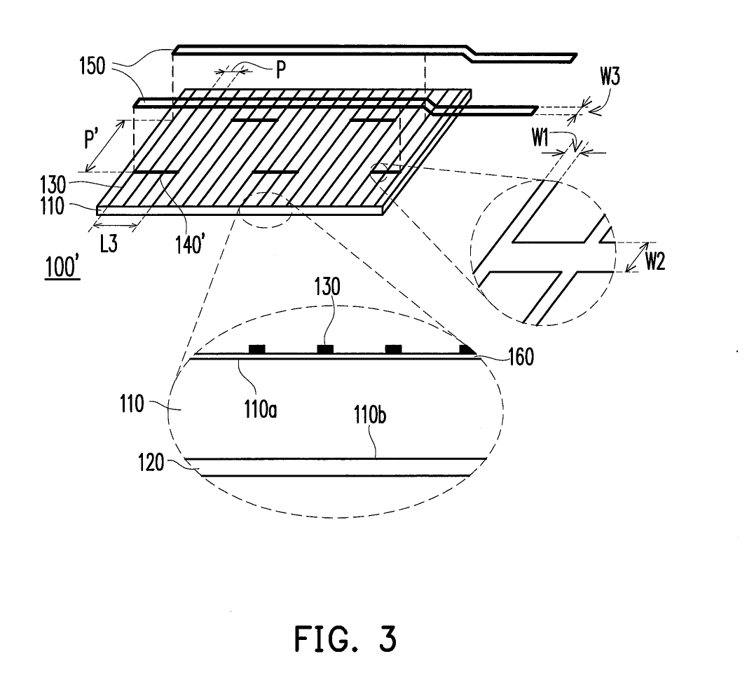

FIG. 3 is a schematic diagram of a solar cell according to another embodiment of the invention. Referring to FIG. 3, the solar cells 100′ of this embodiment is similar to the solar cells 100 of the first embodiment except that each of the bus bars 140′ has a plurality of bar-shape patterns, and a length of each of the bar-shape patterns that is sufficient to electrically connected to three or more conductive fingers 130 simultaneously. The bar-shape patterns that are covered by the same connection ribbon 150 are electrically connected to each other. For example, the conductive fingers 130 are arranged in an equal arrangement pitch P, and the length L3 of each of the bar-shape patterns is substantially equal to three times of the arrangement pitch P.

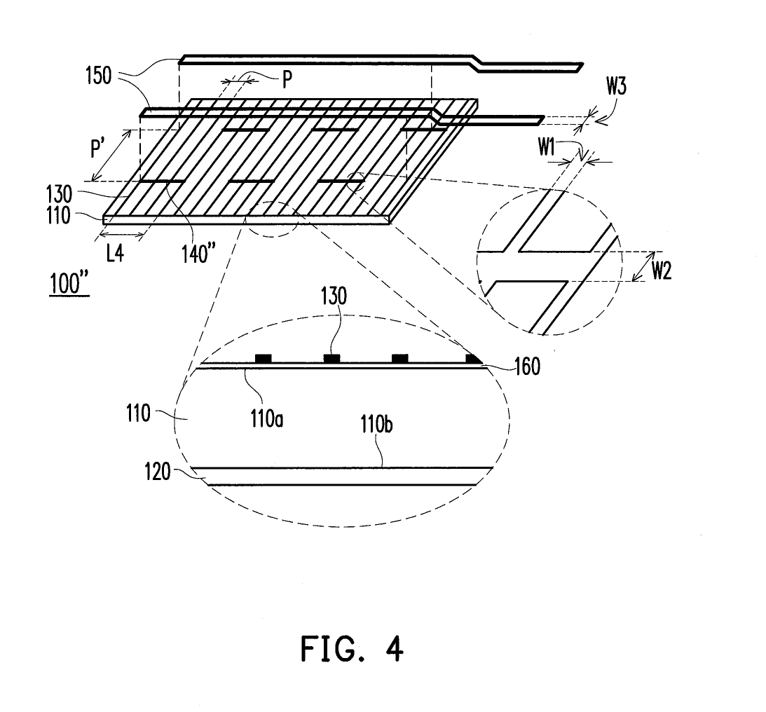

FIG. 4 is a schematic diagram of a solar cell according to still another embodiment of the invention. Referring to FIG. 4, the solar cells 100″ of this embodiment is similar to the solar cells 100 of the first embodiment except that each of the bus bars 140″ has a plurality of bar-shape patterns, and a length of each of the bar-shape patterns that is sufficient to electrically connected to three or more conductive fingers 130 simultaneously. All the bar-shape patterns are electrically connected to each other through at least parts of the conductive fingers 130. For example, the conductive fingers 130 are arranged in an equal arrangement pitch P, and the length L4 of each of the bar-shape patterns is substantially equal to three times of the arrangement pitch P.

In the solar cell and the solar cell module of the invention, since the bus bar covered by the single connection ribbon has a discontinuous pattern, the material used for fabricating the bus bar can be reduced, so as to reduce the fabrication cost of the solar cell and the solar cell module.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A solar cell, comprising:
a photoelectric conversion layer, having a front surface and a back surface;
a back electrode, disposed on the back surface of the photoelectric conversion layer;
a plurality of conductive fingers parallel to each other, disposed on the front surface of the photoelectric conversion layer;
at least one bus bar, disposed on the front surface of the photoelectric conversion layer, and electrically connected to the conductive fingers; and
at least one connection ribbon, covering the bus bar and electrically connected to the bus bar, the bus bar covered by a single connection ribbon having a discontinuous pattern.

2. The solar cell as claimed in claim 1, wherein an extending direction of the bus bar is different to an extending direction of the conductive fingers.

3. The solar cell as claimed in claim 1, wherein a line width of the bus bar is greater than a line width of the conductive finger.

4. The solar cell as claimed in claim 1, wherein the connection ribbon comprises a solder coated copper ribbon.

5. The solar cell as claimed in claim 1, wherein a line width of the connection ribbon is substantially the same to a line width of the bus bar.

6. The solar cell as claimed in claim 1, wherein the number of the at least one bus bar is n, and n is an integer greater than or equal to 2.

7. The solar cell as claimed in claim 1, wherein the discontinuous pattern comprises a plurality of bar-shape patterns parallel to each other, and the bar-shape patterns parallel to each other are arranged along a straight line.

8. The solar cell as claimed in claim 7, wherein each of the bar-shape patterns is electrically connected to at least two of the conductive fingers.

9. The solar cell as claimed in claim 7, wherein the bar-shape patterns are electrically connected to each other through at least parts of the conductive fingers.

10. The solar cell as claimed in claim 1, wherein materials of the bus bar and the conductive fingers are substantially the same.

11. A solar cell module, comprising a plurality of the solar cells as claimed in claim 1, wherein the solar cells are arranged in an array, and each of the connection ribbons electrically connected to the bus bar extends to the underneath of an adjacent solar cell to electrically connect a back electrode of the adjacent solar cell.

12. The solar cell module as claimed in claim 11, wherein an extending direction of the bus bar is different to an extending direction of the conductive fingers.

13. The solar cell module as claimed in claim 11, wherein a line width of the bus bar is greater than a line width of the conductive finger.

14. The solar cell module as claimed in claim 11, wherein the connection ribbon comprises a solder coated copper ribbon.

15. The solar cell module as claimed in claim 11, wherein a line width of the connection ribbon is substantially the same to a line width of the bus bar.

16. The solar cell module as claimed in claim 11, wherein the number of the at least one bus bar is n, and n is an integer greater than or equal to 2.

17. The solar cell module as claimed in claim 11, wherein the discontinuous pattern comprises a plurality of bar-shape patterns parallel to each other, and the bar-shape patterns parallel to each other are arranged along a straight line.

18. The solar cell as claimed in claim 17, wherein each of the bar-shape patterns is electrically connected to at least two of the conductive fingers.

19. The solar cell as claimed in claim 17, wherein the bar-shape patterns are electrically connected to each other through at least parts of the conductive fingers.

20. The solar cell module as claimed in claim 11, wherein materials of the bus bar and the conductive fingers are substantially the same.
